(19) United States
(12) Patent Application Publication
(10) Pub. No.: US 2023/0034399 A1
(43) Pub. Date: Feb. 2, 2023

(54) SUBSTRATE PROCESSING SYSTEM AND METHOD OF PROCESSING SUBSTRATE

(71) Applicant: Tokyo Electron Limited, Tokyo (JP)

(72) Inventors: Risako MATSUDA, Miyagi (JP); Keita SHOUJI, Miyagi (JP); Kazuaki TAKAAI, Miyagi (JP)

(21) Appl. No.: 17/873,374

(22) Filed: Jul. 26, 2022

(30) Foreign Application Priority Data
Jul. 27, 2021 (JP) 2021-122385

(51) Int. Cl. H01L 21/67; G01F 1/34; G01F 1/50

(52) U.S. Cl. CPC H01L 21/67253; G01F 1/34; G01F 1/50

(57) ABSTRACT

A substrate processing system includes a chamber group including chambers configured to process a substrate in a desired process gas, a gas box group including gas boxes configured to supply the process gas to each of the chambers, a flow rate measuring device configured to measure a flow rate of the process gas supplied from the gas box group, and an exhaust device connected to the chamber group and the flow rate measuring device. The flow rate measuring device includes a measuring instrument and a measurement pipe connected to the gas box group and the measuring instrument and configured to flow the process gas through the gas box group and the measuring instrument. The measurement pipe includes branch pipes connected to each of the gas boxes, a main pipe connected to each of the branch pipes and the measuring instrument, and branch pipe valves provided in the branch pipes.

### CROSS-REFERENCE TO RELATED APPLICATION

This application is based upon and claims the benefit of priority from Japanese Patent Application No. 2021-122385, filed on Jul. 27, 2021, the entire contents of which are incorporated herein by reference.

### TECHNICAL FIELD

The present disclosure relates to a substrate processing system and a method of processing a substrate.

### BACKGROUND

Patent Document 1 discloses a method of obtaining a gas flow rate in a substrate processing system using a flow rate measurement system. The method described in Patent Document 1 includes a process of obtaining the flow rate of a gas output from one flow rate controller by executing a calculation based on the volume, pressure, and temperature of a gas flow path provided in the flow rate measurement system.

### PRIOR ART DOCUMENT

### Patent Document

Japanese Laid-Open Publication No. 2019-120617

### SUMMARY

According to one embodiment of the present disclosure, a substrate processing system includes a chamber group including chambers configured to process a substrate in a desired process gas, a gas box group including gas boxes configured to supply the process gas to each of the chambers, a flow rate measuring device configured to measure a flow rate of the process gas supplied from the gas box group, and an exhaust device connected to the chamber group and the flow rate measuring device. The flow rate measuring device includes a measuring instrument and a measurement pipe connected to the gas box group and the measuring instrument and configured to flow the process gas through the gas box group and the measuring instrument. The measurement pipe includes branch pipes connected to each of the gas boxes, a main pipe connected to each of the branch pipes and the measuring instrument, and branch pipe valves provided in the branch pipes. The measuring instrument includes one or more pressure sensors configured to measure an internal pressure of the measuring instrument, a temperature sensor configured to measure an internal temperature of the measuring instrument, a measuring instrument primary valve provided at an end portion of the side connected to the measurement pipe in the measuring instrument, and a measuring instrument secondary valve provided at an end portion of the side connected to the exhaust device.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic plan view showing a configuration of a wafer processing system according to an embodiment.

FIG. 2 is a schematic view showing a pipe system constituting flow paths of process gases in the wafer processing system according to the embodiment.

FIG. 3 is a flowchart showing a method of measuring a gas flow rate according to the embodiment.

FIG. 4 is an explanatory diagram showing opening/closing timings of valves in the method of measuring the gas flow rate according to the embodiment.

FIG. 5 is a schematic plan view showing the configuration of a wafer processing system according to another embodiment.

FIG. 6 is a schematic view showing a pipe system constituting flow paths of process gases in the wafer processing system according to another embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a semiconductor device manufacturing process, a semiconductor substrate (hereinafter referred to as a “wafer”) is subjected to various kinds of gas processes such as a film-forming process, a cleaning process, and other plasma processes under a desired gas atmosphere. These gas processes are performed, for example, in a wafer processing system provided with a vacuum process chamber (hereinafter may be referred to as a “chamber”) whose interior can be controlled to a reduced pressure atmosphere. In this wafer processing system, it is important to precisely control the flow rate of a gas to be supplied to the vacuum process chamber in order to appropriately perform various kinds of gas processes on the wafer.

A flow rate measuring device described in Patent Document 1 is a system for measuring a gas flow rate in such a wafer processing system. In the flow rate measuring device described in Patent Document 1, the gas flow rate is obtained based on the volume, pressure, and temperature of the gas flow path and the measured value of one flow rate controller by controlling the supply and exhaust of gas to the gas flow path provided in the flow rate measuring device.

By the way, when designing a substrate processing system, it is required to mount more chambers in one wafer processing system from the viewpoint of a user's requirement and efficiency of substrate processing. However, in the case where the number of mounted chambers is increased in this way, when the gas flow rate is measured by the method described in Patent Document 1, the number of gas flow paths increases according to the number of chambers, so that the filling volume of the gas in the flow rate measuring device becomes large and the length of pipes for filling the gas also becomes long. Thus, there is a concern that it may take time to measure the flow rate.

In order to shorten the time required for such flow rate measurement, for example, in order to reduce the filling volume of the gas in one flow rate measuring device, it is conceivable to mount two or more flow rate measuring devices. However, if the number of flow rate measuring devices is simply increased in this way, the cost for installing the flow rate measuring devices increases and a flow rate measurement error between the flow rate measuring devices (a difference between systems) increases. Therefore, in the method of measuring the gas flow rate using the flow rate measuring device described in Patent Document 1, there is room for improvement in the measurement time, especially when the number of chambers installed in one wafer processing system is increased.

A technique according to the present disclosure has been devised in view of the above circumstances and shortens the time required for a gas flow rate measurement performed by using a flow rate measuring device in a substrate processing system. Hereinafter, a wafer processing system as a substrate processing system according to an embodiment will be described with reference to the drawings. Throughout the present disclosure and the drawings, elements having substantially the same functional configuration are denoted by the same reference numerals, and therefore, explanation thereof will be omitted.

### <Wafer Processing System>

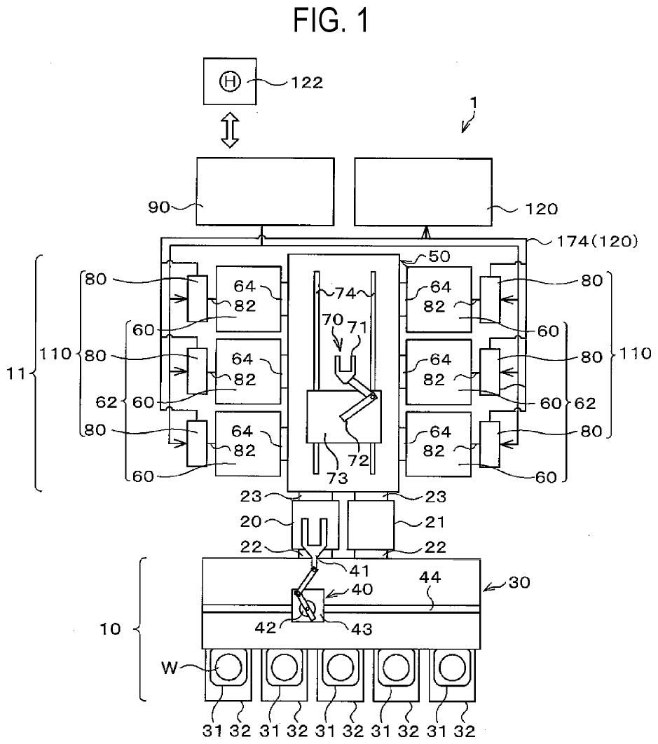

A wafer processing system 1 according to a present embodiment will be described. FIG. 1 is a schematic plan view showing a configuration of the wafer processing system 1 according to the present embodiment. In the wafer processing system 1, a wafer W, as a substrate is subjected to desired gas processes such as a film-forming process, a cleaning process, and other plasma processes.

As shown in FIG. 1, the wafer processing system 1 has a configuration in which an atmosphere part 10 and a decompression part 11 are integrally connected via load lock modules 20 and 21. The atmosphere part 10 includes an atmosphere module that performs a desired process on the wafer W under an atmospheric pressure atmosphere. The decompression part 11 includes a decompression module that performs a desired process on the wafer W under a decompression atmosphere.

The load lock modules 20 and 21 are provided so as to connect a loader module 30, which will be described later, in the atmosphere part 10 and a transfer module 50, which will be described later, in the decompression part 11, via gate valves 22 and 23, respectively. The load lock modules 20 and 21 are configured to temporarily hold the wafer W. Further, the load lock modules 20 and 21 are configured so as to switch their insides between the atmospheric pressure atmosphere and the decompression atmosphere (vacuum state).

The atmosphere part 10 has the loader module 30 provided with a wafer transfer mechanism 40, which will be described later, and a load port 32 on which a FOUP (Front Opening Unified Pod) 31 capable of storing a plurality of wafers W is placed. The loader module 30 may be adjacently provided with an orientation module (not shown) for adjusting the horizontal orientation of the wafer W, a storage module for storing a plurality of wafers W (not shown), and the like.

The loader module 30 has a rectangular housing inside, and the inside of the housing is maintained in the atmospheric pressure atmosphere. A plurality of load ports 32, for example, five load ports, are arranged side by side on one side surface constituting a long side of the housing of the loader module 30. The load lock modules 20 and 21 are arranged side by side on the other side surface constituting the long side of the housing of the loader module 30.

The wafer transfer mechanism 40 for transporting the wafer W is provided inside the loader module 30. The wafer transfer mechanism 40 has a transfer arm 41 that holds and moves the wafer W, a rotary table 42 that rotatably supports the transfer arm 41, and a rotary mounting table 43 on which the rotary table 42 is mounted. Further, a guide rail 44 extending in the longitudinal direction of the loader module 30 is provided inside the loader module 30. The rotary mounting table 43 is provided on the guide rail 44, and the wafer transfer mechanism 40 is configured to be movable along the guide rail 44.

The decompression part 11 has the transfer module 50 that internally transfers the wafer W, and a chamber 60 in which a desired process is performed on the wafer W transferred from the transfer module 50. The insides of the transfer module 50 and the chamber 60 are each maintained in the decompression atmosphere. In the present embodiment, a plurality of chambers 60, for example, six chambers, are connected to one transfer module 50. In the present disclosure, a group of a plurality of chambers 60, for example, six chambers, connected to the one transfer module 50 is referred to as one chamber group 62. The number and arrangement of chambers 60 in one chamber group 62 is not limited to the present embodiment and may be arbitrarily set.

The chambers 60 are provided adjacent to the transfer module 50 via gate valves 64, respectively. In the chambers 60, arbitrary gas processes such as a film-formation process, a cleaning process, and other plasma processes are performed depending on the purpose of wafer processing.

The transfer module 50 has a rectangular housing inside and is connected to the load lock modules 20 and 21 as described above. The transfer module 50 transfers the wafer W, which is loaded into the load lock module 20, to one chamber 60 where a desired process is performed on the wafer W, and then unloads the processed wafer W to the atmosphere part 10 via the load lock module 21.

A wafer transfer mechanism 70 for transferring the wafer W is provided inside the transfer module 50. The wafer transfer mechanism 70 has a transfer arm 71 that holds and moves the wafer W, a rotary table 72 that rotatably supports the transfer arm 71, and a rotary mounting table 73 on which the rotary table 72 is mounted. Further, a guide rail 74 extending in the longitudinal direction of the transfer module 50 is provided inside the transfer module 50. The rotary mounting table 73 is provided on the guide rail 74, and the wafer transfer mechanism 70 is configured to be movable along the guide rail 74.

Then, in the transfer module 50, the wafer W held by the load lock module 20 is received by the transfer arm 71 and is transferred to an arbitrary chamber 60. Further, the transfer arm 71 holds the wafer W that has been subjected to the desired process in the chamber 60, and unloads it to the load lock module 21.

Further, the decompression part 11 is provided with a plurality of gas boxes 80, for example, six gas boxes corresponding to the chambers 60, in the present embodiment, that supply gases to the chambers 60, and a main gas unit 90 that accommodates a gas control unit for controlling the supply of gases to the respective gas boxes 80 (the chambers 60). Each gas box 80 and the corresponding chamber 60 are connected by a connection pipe 82 through which a process gas can flow.

In the present embodiment, the six gas boxes 80 connected to the respective six chambers 60 to supply the process gases are collectively referred to as one gas box group 110. The number and arrangement of gas boxes 80 in one gas box group 110 is not limited to the present embodiment and may be arbitrarily set. Each gas box 80 is further connected to a flow rate measuring device 120. Specifically, each gas box 80 is connected to a measurement pipe 172, which will be described later, as the flow rate measuring device 120.

The wafer processing system 1 described above is provided with a controller 122. The controller 122 is, for example, a computer equipped with a CPU, a memory, or the like, and has a program storage part (not shown). The program storage part stores a program for controlling the gas process of the wafer W in the wafer processing system 1. Further, the program storage part also stores a program for controlling a process gas supply operation which will be described later. The above programs have been recorded on a computer-readable storage medium H and may be installed on the controller 122 from the storage medium H.

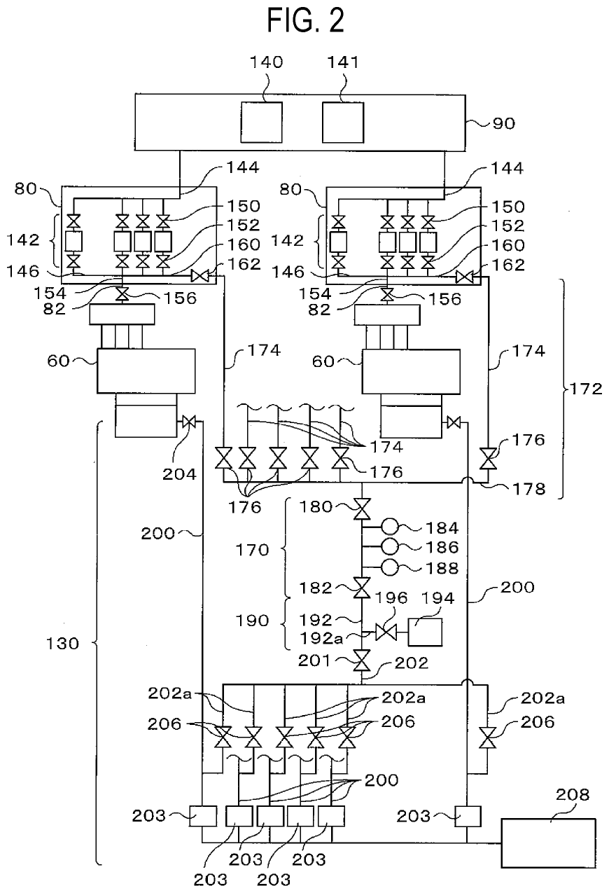

In the wafer processing system 1, the flow rate measuring device 120 is connected in order to measure the flow rates of the process gases supplied from the gas boxes 80. The flow rate measuring device 120 provides flow paths of the process gases and various sensors used in process gas flow rate measurement using a build-up method. Hereinafter, the flow rate measuring device 120 in the wafer processing system 1 according to the present embodiment will be described with reference to FIG. 2.

FIG. 2 is a schematic view showing a pipe system constituting flow paths of the process gases in the wafer processing system 1 according to the present embodiment. In addition, in the present disclosure, the “pipe” is configured so that a process gas can flow inside. When the process gas is supplied to each “pipe,” a “flow path” of the process gas may be formed inside the “pipe.” Further, when any one of the constituent elements of the wafer processing system 1 is connected to any one of the “pipes” or two or more “pipes” are connected to each other, a continuous “flow path” is formed inside them.

In the present embodiment, a process gas is supplied from each gas box 80 to the corresponding chamber 60, is provided for processing of the wafer W, and then is supplied to either a wafer processing flow path A through which the process gas is exhausted by an exhaust device 130 or a measurement flow path B through which the process gas is exhausted by the exhaust device 130 after being supplied from the gas box 80 to the flow rate measuring device 120 for measurement of the flow rate of the process gas. The wafer processing flow path A and the measurement flow path B will be described later.

The main gas unit 90 is provided with gas sources 140 for supplying one or more gases to the respective gas boxes 80, and flow rate controllers 141. In one embodiment, the main gas unit 90 is configured to supply one or more gases from the corresponding gas sources to the respective gas boxes 80 via the corresponding flow rate controllers 141. Each flow rate controller 141 may include, for example, a mass flow controller or a pressure control type flow rate controller. In the following description, a mixed gas including one or more gases supplied from the main gas unit 90 is referred to as a “process gas” that is used for a gas process in the chamber 60 or whose flow rate is measured by the flow rate measuring device 120.

The gas box 80 includes a plurality of flow rate controllers 142 and pipes connecting them to form a flow path.

In the present embodiment, the pipe system in the gas box 80 is configured as follows. An upstream side pipe 144 is connected to the gas source 140 with the gas source 140 side as the most upstream, a plurality of flow rate controllers 142, for example, four flow rate controllers, provided in the present embodiment, are connected to the upstream side pipe 144, a downstream side pipe 146 is connected to the downstream side of the flow rate controllers 142, and the chamber 60 and the flow rate measuring device 120 are connected to the downstream of the downstream side pipe 146. In the gas box 80, the “upstream side” refers to the supply path upstream side of the process gas (the gas source 140 side), and the “downstream side” refers to the supply path downstream side of the process gas (the chamber 60 side, the flow rate measuring device 120 side). Further, in FIG. 2, among the above six gas boxes 80, only two gas boxes are shown, and the other four are omitted.

The flow rate controller 142 is provided with a flow rate controller primary valve 150 on the upstream side, and the flow rate controller 142 is connected to the upstream side pipe 144 via the flow rate controller primary valve 150. Further, the flow rate controller is provided with a flow rate controller secondary valve 152 on the downstream side, and the flow rate controller 142 is connected to the downstream side pipe 146 via the flow rate controller secondary valve 152.

The number and arrangement of the flow rate controllers 142 in the gas box 80 are not limited to the present embodiment and may be arbitrarily set. Each flow rate controller 142 may be a mass flow controller or a pressure control type flow rate controller 142. Further, the number and arrangement of gas sources 140 are not limited to the present embodiment and may be arbitrarily set. The gas source 140 may be provided either inside or outside the main gas unit 90.

The downstream side pipe 146 includes a connection pipe 154 connected to the connection pipe 82 described above. The connection pipe 82 includes a first output valve 156. Further, the downstream side pipe 146 includes a connection pipe 160 connected to the flow rate measuring device 120, and a second output valve 162 provided in the connection pipe 160.

In the gas box 80 according to the present embodiment, when a process gas is supplied from one of the plurality of flow rate controllers 142 and is supplied to a chamber in the wafer processing flow path A, the process gas is supplied to the chamber through the connection pipe 154 by opening the first output valve 156 and closing the second output valve 162. Conversely, when the process gas is supplied to the flow rate measuring device 120 in the measurement flow path B, the process gas is supplied to the flow rate measuring device 120 through the connection pipe 160 by opening the second output valve 162 and closing the first output valve 156.

The flow rate measuring device 120 according to the present embodiment includes a measuring instrument 170 and a measurement pipe 172 connected to the gas box group 110 on the upstream side and connected to the measuring instrument 170 on the downstream side.

The measurement pipe 172 includes a plurality of branch pipes 174 connected to the second output valve 162 in each gas box 80 on the upstream side, branch pipe valves 176 provided in the plurality of branch pipes 174, respectively, and a main pipe 178 connected to each of the plurality of branch pipes 174 on the upstream side and connected to the measuring instrument 170 on the downstream side. In the flow rate measuring device 120, the “upstream side” refers to the supply path upstream side of the process gas (the gas box 80 side), and the “downstream side” refers to the supply path downstream side of the process gas (the exhaust device 130 side).

One branch pipe 174 may be provided for each gas box 80. In the present embodiment, since six gas boxes 80 are provided, a total of six branch pipes 174 may be provided. Further, one branch pipe valve 176 may be provided for each branch pipe 174. In FIG. 2, branch pipes 174 are similarly connected to the other four gas boxes 80 (not shown), and some portions of the four branch pipes 174 are omitted. However, the number and arrangement of branch pipes 174 and branch pipe valves 176 are not limited to the present embodiment and may be arbitrarily set. For example, when changing the number of gas boxes 80, the number of branch pipes 174 may be changed accordingly. Further, when a plurality of pipes and second output valves 162 on the flow rate measuring device 120 side are provided in the downstream side pipe 146 of the gas box, the number of branch pipes 174 connected to each gas box may be changed accordingly.

In the present embodiment, one main pipe 178 is provided for one gas box group 110. Since the wafer processing system 1 has one gas box group 110, one main pipe 178 may be provided. However, the number and arrangement of main pipes 178 are not limited to the present embodiment and may be arbitrarily set.

The measuring instrument 170 is connected to the main pipe 178 via a measuring instrument primary valve 180 on the upstream side and is connected to a calibration system 190, which will be described later, via a measuring instrument secondary valve 182 on the downstream side. The measuring instrument 170 includes one or more pressure sensors 184 and 186 (two pressure sensors in the present embodiment) configured to measure the internal pressure of the measuring instrument 170, and a temperature sensor 188 configured to measure the internal pressure of the measuring instrument 170.

In the present embodiment, the measuring instrument 170 is configured to form a flow path inside so that the process gas can flow through. Therefore, the inside of the measuring instrument 170 provided with the pressure sensors and the temperature sensor is a region sandwiched between the measuring instrument primary valve 180 and the measuring instrument secondary valve 182, and refers to the internal space of the measuring instrument 170 itself that forms a flow path for the process gas. However, the configuration of the measuring instrument 170 is not limited to the present embodiment and may be arbitrarily set. For example, the measuring instrument 170 may adopt any measuring instrument 170 that includes an upstream side valve and a downstream side valve capable of opening or closing the flow of the process gas, and an internal space constituting the flow path of the process gas sandwiched between them and is configured to enable measurements of the volume, pressure, and temperature of the internal space constituting the flow path of the process gas.

In the present embodiment, the calibration system 190 is provided at the downstream of the flow rate measuring device 120. The calibration system 190 includes a reference device pipe 192, a reference device 194, and a reference device valve 196. The reference device pipe 192 is connected to the measuring instrument secondary valve 182 on the upstream side and is connected to the exhaust device 130 on the downstream side. A branch path 192a is provided in the reference device pipe 192, and the reference device 194 is connected to the branch path 192a via the reference device valve 196.

The exhaust device 130 is configured to exhaust the process gas at the downstream of the wafer processing flow path A and the measurement flow path B. In the present embodiment, an exhaust pipe 200 connected to the downstream side of each chamber 60 and an exhaust pipe 202 connected to the downstream side of the measuring instrument 170 (the downstream side of the reference device pipe 192 in the present embodiment) via an exhaust device valve 201 are provided. An exhaust mechanism (a vacuum pump 203 in the present embodiment) is connected to the exhaust pipe 200. The exhaust pipe 202 has a plurality of exhaust branch pipes 202a. The exhaust pipe 200 and the exhaust branch pipes 202a are provided so as to correspond to the gas boxes 80 connected to the upstream thereof. Valves 204 and 206 are provided on the exhaust pipe 200 and the exhaust branch pipes 202a, and by controlling the opening/closing of these valves, the process gas supplied from each corresponding gas box 80 can be controlled to be exhausted individually. Further, in FIG. 2, exhaust pipes 200 are similarly connected to the downstream side of chambers 60 (not shown), and some portions of these exhaust pipes 200 are omitted.

Here, the wafer processing flow path A and the measurement flow path B will be described. In the wafer processing system 1 configured as described above, the wafer processing flow path A refers to a flow path of a process gas when the process gas supplied from the gas source 140 flows inside the upstream side pipe 144, the flow rate controller 142, and the downstream side pipe 146 of each gas box 80, the connection pipe 82, the chamber 60, and the exhaust pipe 200 to form a flow path. The measurement flow path B refers to a flow path of a process gas when the process gas supplied from the gas source 140 flows inside the upstream side pipe 144, the flow rate controller 142, and the downstream side pipe 146 of each gas box 80, the measurement pipe 172, the measuring instrument 170, the calibration system 190, and the exhaust pipe 202 to form a flow path.

In one embodiment, when the process gas is supplied from one gas box 80 to one chamber 60 in the wafer processing flow path A, a valve in one exhaust pipe 200 connected to the downstream of the chamber is opened to exhaust the process gas through the one exhaust pipe 200. In this case, when the process gas is supplied from the one gas box 80 to the flow rate measuring device 120 in the measurement flow path B, a valve in one exhaust branch pipe 202a connected to the one exhaust pipe 200 is opened to exhaust the process gas through the one exhaust branch pipe 202a and the one exhaust pipe 200. Therefore, the process gas supplied from one gas box, in any one of the wafer processing flow path A and the measurement flow path B, can be exhausted from the one exhaust pipe 200 after merging. A detoxifying device 208 is connected to the one exhaust pipe 200 after merging and detoxifies the exhausted process gas.

Although various exemplary embodiments have been described above, various additions, omissions, substitutions, and changes may be made without being limited to the above-described exemplary embodiments. It is also possible to combine elements in different embodiments to form other embodiments.

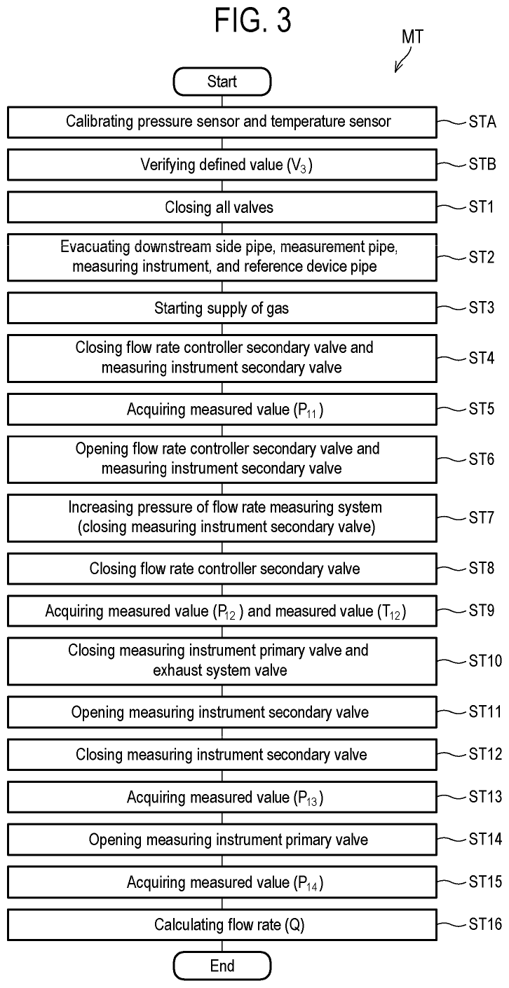

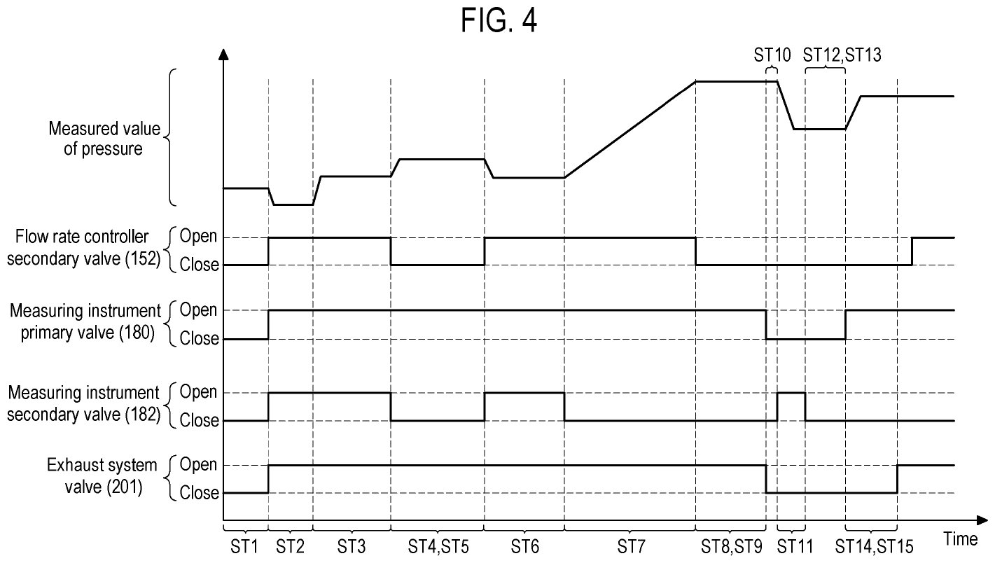

The wafer processing system 1 according to the present embodiment is configured as described above. Next, a method of measuring a gas flow rate using the flow rate measuring device 120 as a wafer processing method in the wafer processing system 1 will be described with reference to FIGS. 3 and 4.

FIG. 3 is a flowchart showing a method of obtaining a gas flow rate according to one embodiment. A method MT shown in FIG. 3 is executed using the flow rate measuring device 120 in order to obtain the gas flow rate in the wafer processing system 1. As the wafer processing system 1, the ones described above and shown in FIGS. 1 and 2 can be used. In the method MT, it is assumed that the flow rate of a process gas output from one flow rate controller 142 in one of the six gas boxes of the wafer processing system is measured. Hereinafter, when a gas box is simply referred to, it refers to the above-mentioned one gas box used for measurement. When a flow rate controller 142 is simply referred to, it refers to the above-mentioned one flow rate controller 142 used for measurement. Further, when a branch pipe 174 and a branch pipe valve 176 are simply referred to, they refer to a branch pipe 174 connected to the above-mentioned one gas box and a branch pipe valve 176 provided in the branch pipe 174, respectively. However, the same method MT can be adopted in a case where a process gas is supplied from a gas box other than the above-mentioned one gas box in the gas box group 110.

The method MT includes steps ST1 to ST16. In one embodiment, the method MT may further include step STA in addition to the steps ST1 to ST16. In one embodiment, the method MT may further include step STB. The step STA is a step of calibrating the pressure sensor and the temperature sensor of the measuring device 170 in the flow rate measuring device 120 by using the calibration system 190, and may use the step STA described in Patent Document 1. Further, the step STB is a step of verifying the reliability of capacity V₃ of the measuring instrument 170 by using the calibration system 190, and may use the step STB described in Patent Document 1.

FIG. 4 is a timing diagram related to the method shown in FIG. 3. In the timing diagram of FIG. 4, the horizontal axis indicates time, and the vertical axis indicates a measured value of the pressure in the measuring instrument 170, the opened/closed state of the flow rate controller secondary valve 152, the opened/closed state of the measuring instrument primary valve 180, the opened/closed state of the measuring instrument secondary valve 182, and the opened/closed state of the exhaust device valve 201.

In the step ST1 of the method MT, a 0th state is formed in which all the valves of the wafer processing system are closed. In the present embodiment, all valves include the plurality of flow rate controller primary valves 150, the plurality of flow rate controller secondary valves 152, the first output valve 156, and the second output valve 162 in the plurality of gas boxes, and the plurality of branch pipe valves 176, the measuring instrument primary valve 180, the measuring instrument secondary valve 182, the reference device valve 196, the exhaust device valve 201, the valve 204, and the valve 206 in the flow rate measuring device 120.

In the step ST2 of the method MT, from the first state, first, the flow rate controller secondary valve 152, the second output valve 162 of the gas box 80, the branch pipe valve 176, the measuring instrument primary valve 180, the measuring instrument secondary valve 182, the exhaust device valve 130, and the exhaust pipe valve are opened. Subsequently, the downstream side pipe 146 in the gas box, the measurement pipe 172, the measuring instrument 170, and the reference device pipe 192 are evacuated by the exhaust device 130.

According to the steps ST1 and ST2, in the measurement pipe 172 in the present embodiment, the branch pipe valve 176 in the branch pipe 174 connected to a gas box other than the one gas box used for measurement is closed, and the branch pipe valve 176 in the branch pipe 174 connected to the one gas box used for measurement is opened. Therefore, the measurement pipe 172 consists of three regions of the branch pipe 174 connected to the one gas box 80 used for measurement, the main pipe 178, and the branch pipe 174 on the downstream side of the branch pipe valve 176 in the branch pipe 174 connected to a gas box 80 other than the one gas box 80. In other words, the measurement pipe 172 consists of a region excluding the branch pipe 174 on the upstream side of the branch pipe valve 176 in the branch pipe 174 connected to a gas box 80 other than the one gas box 80 from a region where all the branch pipes 174 and the main pipe 178 are combined. In the above step ST1 and the following steps ST2 to ST16, the measurement pipe 172 refers to a portion of the measurement pipe 172 including the above region.

In the subsequent step ST3, the flow rate controller primary valve 150 is opened to start the supply of a gas from the flow rate controller 142. In the subsequent step ST4, the flow rate controller secondary valve 152 and the measuring instrument secondary valve 182 are closed. By executing the step ST4, a second state, in which a gas output from the flow rate controller 142 of the gas box 80 is enclosed between the flow rate controller secondary valve 152 and the measuring instrument secondary valve 182, that is, inside the downstream side pipe 146 of the gas box 80, the measurement pipe 172, and the measuring instrument 170, is formed.

In the subsequent step ST5, a measured value Pu of the internal pressure of the measuring instrument 170 is acquired by the pressure sensor 184 and/or the pressure sensor 186. The measured value P₁₁ may be an average of a measured value acquired by the pressure sensor 184 and a measured value acquired by the pressure sensor 186. Further, in the step ST5, the measured value P₁₁ can be acquired when the measured value acquired by the pressure sensor 184 and/or the pressure sensor 186 is stable. The measured value acquired by the pressure sensor 184 and/or the pressure sensor 186 is determined to be stable when the fluctuation amount thereof is equal to or less than a predetermined value.

In the subsequent step ST6, the flow rate controller secondary valve 152 and the measuring instrument secondary valve 182 are opened. In the subsequent step ST7, the internal pressures of the downstream side pipe of the gas box, the measurement pipe 172, and the measuring instrument 170 are increased. Specifically, in the step ST7, the measuring instrument secondary valve 182 is closed. That is, in the step ST7, a third state, in which a gas is supplied from the flow rate controller 142 of the gas box to the downstream side pipe of the gas box, the measurement pipe 172, and the measuring instrument 170, and also, the measuring instrument secondary valve 182 is closed, is formed. In this third state, the internal pressures of the downstream side pipe 146 of the gas box 80, the measurement pipe 172, and the measuring instrument 170 rise.

In the subsequent step ST8, a fourth state is formed from the third state by closing the flow rate controller secondary valve 152.

In the subsequent step ST9, a measured value P₁₂ of the internal pressure of the measuring instrument 170 in the fourth state is acquired by the pressure sensor 184 and/or the pressure sensor 186, and a measured value T₁₂ of the internal temperature of the measuring instrument 170 in the fourth state is acquired by the temperature sensor 188. The measured value P₁₂ may be an average of a measured value acquired by the pressure sensor 184 and a measured value acquired by the pressure sensor 186. Further, in the step ST9, the measured value P₁₂ and the measured value T₁₂ may be acquired when the measured value acquired by the pressure sensor 184 and/or the pressure sensor 186 are stable and the measured value acquired by the temperature sensor 188 is stable. In that case, the measured value acquired by the pressure sensor 184 and/or the pressure sensor 186 is determined to be stable when the fluctuation amount of the measured value is equal to or less than a predetermined value. Further, the measured value acquired by the temperature sensor 188 is determined to be stable when the fluctuation amount of the measured value is equal to or less than a predetermined value.

In the subsequent step ST10, the measuring instrument primary valve 180 and the exhaust device valve 201 are closed. In the subsequent step ST11, the measuring instrument secondary valve 182 is opened. According to the step ST10 and the step ST11, a fifth state is formed by closing the measuring instrument primary valve 180 and opening the measuring instrument secondary valve 182. In the fifth state, a gas in the measuring instrument 170 in the fourth state is at least partially exhausted. In the fifth state of one embodiment, the gas in the measuring instrument 170 is partially discharged to the reference device pipe 192. In the fifth state of another embodiment, the gas in the measuring instrument 170 may be completely discharged through the reference device pipe 192.

In the subsequent step ST12, a sixth state is formed from the fifth state by closing the measuring instrument secondary valve 182. In one embodiment, in the step ST12, by partially exhausting a gas in the measuring instrument 170 to form the sixth state, the internal pressure of the measuring instrument 170 in the sixth state may be higher than the internal pressure of the evacuated measuring instrument 170. In that case, the gas enclosed in the measuring instrument 170 in the fourth state is partially discharged, that is, not completely discharged, to form the sixth state. Therefore, the time required to form the sixth state from the fourth state is shortened. In one embodiment, step ST12a of opening the exhaust device valve 201 may be added after ST12, and the steps ST1 to ST12a may be repeated to reduce the internal pressure of the measuring instrument 170.

In the subsequent step ST13, a measured value P₁₃ of the internal pressure of the measuring instrument 170 in the sixth state is acquired by the pressure sensor 184 and/or the pressure sensor 186. The measured value P₁₃ may be an average of a measured value acquired by the pressure sensor 184 and a measured value acquired by the pressure sensor 186. Further, in the step ST13, the measured value P₁₃ can be acquired when the measured value acquired by the pressure sensor 184 and/or the pressure sensor 186 is stable. The measured value acquired by the pressure sensor 184 and/or the pressure sensor 186 is determined to be stable when the fluctuation amount thereof is equal to or less than a predetermined value.

In the subsequent step ST14, a seventh state is formed from the sixth state by opening the measuring instrument primary valve 180. In the subsequent step ST15, a measured value P₁₄ of the internal pressure of the measuring instrument 170 in the seventh state is acquired by the pressure sensor 184 and/or the pressure sensor 186. The measured value P₁₄ may be an average of a measured value acquired by the pressure sensor 184 and a measured value acquired by the pressure sensor 186. Further, in the step ST15, the measured value P₁₄ can be acquired when the measured value acquired by the pressure sensor 184 and/or the pressure sensor 186 is stable. The measured value acquired by the pressure sensor 184 and/or the pressure sensor 186 is determined to be stable when the fluctuation amount thereof is equal to or less than a predetermined value.

In the subsequent step ST16, a flow rate Q is obtained. The flow rate Q is the flow rate of a gas output from the flow rate controller 142 of the gas box in the second state. In the step ST16, the calculation of the following equation (1) is executed in order to obtain the flow rate Q.

Q=(P₁₂−P₁₁)/Δt×(1/R)×(V/T) (1)

In the equation (1), Δt is the time length of the execution period of the step ST7, R is the gas constant, and (V/T) includes {V₃/T₁₂×(P₁₂−P₁₃)/(P₁₂−P₁₄)}.

In one embodiment, the specific calculation of the step ST16 is the calculation of the following equation (1a).

Q=(P₁₂−P₁₁)/Δt×(1/R)×{Vst/Tst+V₃/T₁₂×(P₁₂−P₁₃)/(P₁₂−P₁₄)} (1a)

In the equation (1a), Vst is the volume of a flow path between an orifice member (not shown) of the flow rate controller 142 of the gas box 80 and a valve body of the flow rate controller secondary valve 152, and is a predetermined design value. Tst is the temperature in the flow path between the orifice member of the flow rate controller 142 of the gas box and the valve body of the flow rate controller secondary valve 152, and is acquired by the temperature sensor of the flow rate controller 142. Note that Tst can be the temperature acquired in the fourth state. In addition, (Vst/Tst) may be omitted in the equation (1a).

In the method MT, with the measuring instrument secondary valve 182 closed, a gas from one flow rate controller 142 of one gas box is supplied to the downstream side pipe 146 of the gas box, the measurement pipe 172, and the measuring instrument 170 to cause an increase in pressure. By using the rate of this pressure increase, that is, the increase rate of the pressure, in the equation (1), the flow rate of the gas output from the flow rate controller 142 can be obtained. In the equation (1), V/T should essentially include the sum of (V_{E}/T_{E}) and (V₃/T₁₂). That is, the calculation of the equation (1) should be essentially the following equation (1b).

Q=(P₁₂−P₁₁)/Δt×(1/R)×(Vst/Tst+V_{E}/T_{E}+V₃/T₁₂) (1b)

Here, V_{E} is the sum of the volume of the downstream side pipe of the gas box and the volume of the measurement pipe 172, and T_{E} is an internal temperature in the downstream side pipe of the gas box and the measurement pipe 172 in the fourth state.

Here, from Boyle-Charles' law, the following equation (4) is established.

P₁₂×V_{E}/T_{E}+P₁₃×V₃/T₁₂=P₁₄×V_{E}/T_{E}+P₁₄×V₃/T₁₂ (4)

From the equation (4), the sum of (V_{E}/T_{E}) and (V₃/T₁₂) is expressed as shown in the following equation (5).

V_{E}/T_{E}+V₃/T₁₂=V₃/T₁₂+V₃/T₁₂×(P₁₄−P₁₃)/(P₁₂−P₁₄)=V₃/T₁₂×(P₁₂−P₁₃)/(P₁₂−P₁₄) (5)

Therefore, in the equation (1), instead of the sum of (V_{E}/T_{E}) and (V₃/T₁₂), {V₃/T₁₂×(P₁₂−P₁₃)/(P₁₂−P₁₄)} can be used.

The flow rate Q may be obtained for all the flow rate controllers 142 of the gas box 80. Further, the method MT may be sequentially executed for all of the plurality of gas boxes 80.

Further, in the method MT, in executing the steps ST1 to ST16, when the second output valve 162 in one gas box 80 is opened, a hard interlock may be configured so as to close the second output valves 162 in the other gas boxes 80. When the second output valve 162 in one gas box 80 is opened, the hard interlock may be further configured so as to close the first output valve 156 in the one gas box 80 and the other gas boxes 80.

In the measurement pipe 172 of the present embodiment, in the steps ST1 to ST16, the branch pipe valve 176 in the branch pipe 174 connected to a gas box other than the above-mentioned one gas box used for measurement is closed, and the branch pipe valve 176 in the branch pipe 174 connected to the above-mentioned one gas box used for measurement is opened. Therefore, in the steps ST1 to ST16, the measurement pipe 172 consists of three regions of the branch pipe 174 connected to the one gas box used for measurement, the main pipe 178, and the branch pipe 174 on the downstream side of the branch pipe valve 176 in the branch pipe 174 connected to a gas box other than the one gas box. In other words, the measurement pipe 172 consists of a region excluding the branch pipe 174 on the upstream side of the branch pipe valve 176 in the branch pipe 174 connected to a gas box other than the one gas box from a region where all the branch pipes 174 and the main pipe 178 are combined.

Therefore, the volume of the region of the measurement pipe 172 is smaller than the volume of the measurement pipe 172 when the branch pipe valve 176 is not provided. This makes it possible to improve the responsiveness of a change in the internal pressure of the flow rate measuring device 120 in a step, which requires the exhaust and filling of a process gas in the measurement pipe 172, among the steps ST1 to ST16. Specifically, it is possible to shorten the time required for evacuation in the step ST2, the time required for gas supply and pressure stabilization in the step ST3 for forming the second state in the step ST4, the time required for pressure increase and pressure stabilization in the third state in the step ST7, etc.

In the above embodiment, by providing the branch pipe valve 176 in all the branch pipes 174, the improvement in the responsiveness of the step, which requires the exhaust and filling of the process gas in the measurement pipe 172, among the steps ST1 to ST16, has been realized, but the above-mentioned improvement in the responsiveness can be realized by another embodiment.

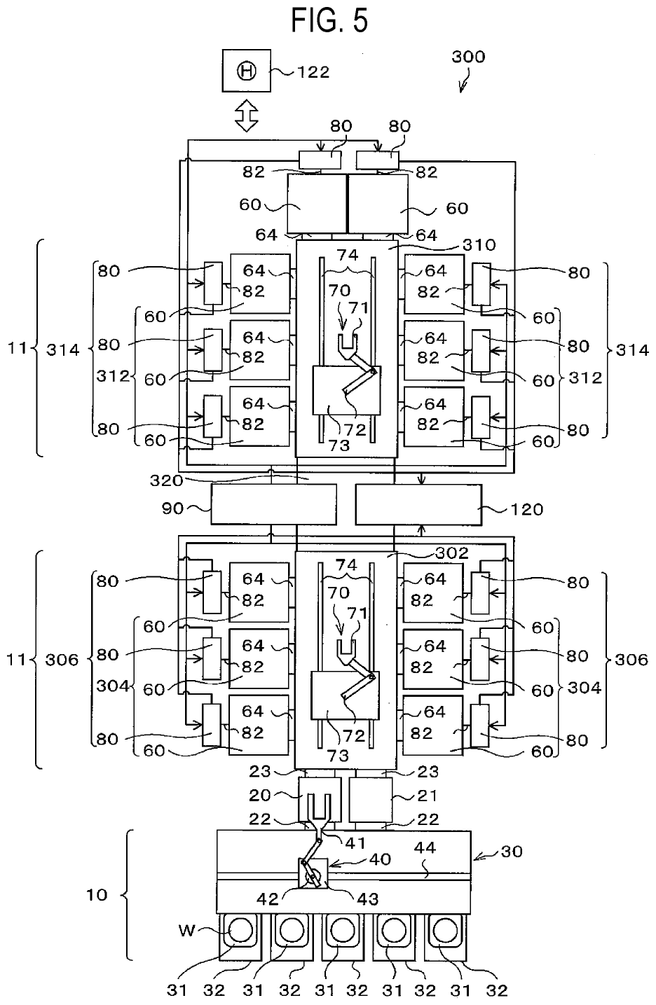

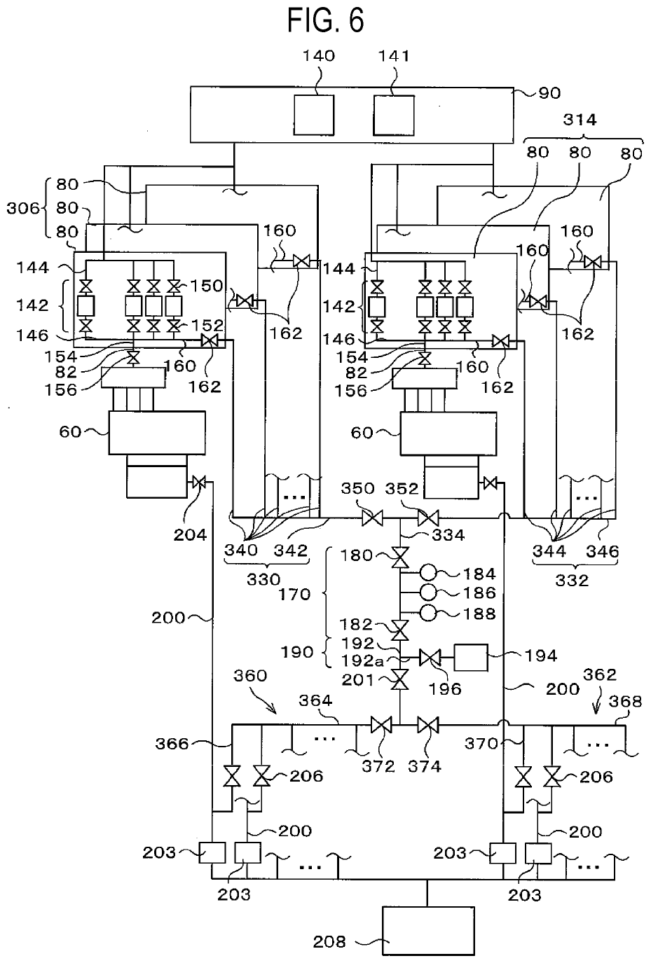

The other embodiment may be a wafer processing system having a plurality of chamber groups and a plurality of gas box groups corresponding to the plurality of chamber groups, as shown in FIG. 5. Hereinafter, a wafer processing system 300 and a wafer processing method in the other embodiment will be described with reference to FIGS. 5 and 6. In the other embodiment, the constituent elements substantially the same as those of the wafer processing system 300 in the one embodiment shown in FIGS. 1 to 4 are denoted by the same reference numerals, and therefore, explanation thereof will be omitted.

FIG. 5 shows an example of a configuration of the wafer processing system 300 in the other embodiment. In the other embodiment, the wafer processing system 300 includes a front transfer module 302, a front chamber group 304 including a plurality of chambers 60 (six chambers 60 in the present embodiment) connected to the front transfer module 302, a front gas box group 306 corresponding to the front chamber group 304, a rear transfer module 310, a rear chamber group 312 including a plurality of chambers 60 (eight chambers 60 in the present embodiment) connected to the rear transfer module 310, and a rear gas box group 314 corresponding to the rear chamber group 312.

Similar to the transfer module 50 in the above one embodiment, the front transfer module 302 has a rectangular housing inside and is connected to the load lock modules 20 and 21. The front transfer module 302 transfers the wafer W, which is loaded into the load lock module 20, to one chamber 60 where a desired process is performed on the wafer W, and then unloads the processed wafer W to the atmosphere part 10 via the load lock module 21.

Unlike the transfer module 50 in the above one embodiment, the rear transfer module 310 is not connected to the load lock modules 20 and 21. Instead, a path module 320 is provided. The rear transfer module 310 is connected to the front transfer module 302 via the path module 320. The front transfer module 302 and the rear transfer module 310 are configured to be able to deliver the wafer W via the path module 320.

Both the front gas box group 306 and the rear gas box group 314 are connected to one flow rate measuring device 120. Hereinafter, the flow rate measuring device 120 in the wafer processing system 300 according to the present embodiment will be described with reference to FIG. 6.

FIG. 6 is a schematic view showing a pipe system constituting a flow path of a process gas in the wafer processing system 300 according to the other embodiment.

In the wafer processing system 300 according to the other embodiment, the flow rate measuring device 120 is connected in order to measure the flow rate of a process gas supplied from one gas box 80 in the front gas box group 306 or the rear gas box group 314.

The flow rate measuring device 120 in the other embodiment includes a measuring instrument 170, a front measurement pipe 330 connected to the front gas box group 306 on the upstream side, a rear measurement pipe 332 connected to the rear gas box group 314 on the upstream side, and a merging pipe 334 connected to the front measurement pipe 330 and the rear measurement pipe 332 on the upstream side and connected to the measuring instrument 170 on the downstream side.

The front measurement pipe 330 includes a plurality of front branch pipes 340 and a front main pipe 342 and is connected to each of the gas boxes 80 of the front gas box group 306 in each of the front branch pipes 340. Further, the rear measurement pipe 332 includes a plurality of rear branch pipes 344 and a rear main pipe 346 and is connected to each of the gas boxes of the rear gas box group 314 in each of the rear branch pipes 344.

The front main pipe 342 and the rear main pipe 346 have a front main pipe valve 350 and a rear main pipe valve 352, respectively.

The exhaust device 130 is configured to exhaust a process gas at the downstream of the wafer processing flow path A and the measurement flow path B. In the present embodiment, an exhaust pipe 200 connected to the downstream side of each chamber 60, a front exhaust pipe 360 connected to the downstream side of the reference device pipe 192, and a rear exhaust pipe 362 are provided. These are provided with an exhaust mechanism, which is the vacuum pump 203 in the present embodiment. The exhaust pipe 200, the front exhaust pipe 360, and the rear exhaust pipe 362 are provided so as to correspond to the gas boxes 80 connected to the upstream thereof. Valves are provided on the exhaust pipe 200, the front exhaust pipe 360, and the rear exhaust pipe 362, and by controlling the opening/closing of these valves, the process gas supplied from each corresponding gas box 80 can be controlled to be exhausted individually.

Specifically, the front exhaust pipe 360 includes a front exhaust main pipe 364 connected to the reference device pipe 192 on the upstream side, and a plurality of front exhaust branch pipes 366 connected to the front exhaust main pipe 364. Each of the plurality of front exhaust branch pipes 366 is provided with a valve 206. The plurality of front exhaust branch pipes 366 are configured to join the exhaust pipe 200 connected to the downstream of the chambers 60, respectively. The rear exhaust pipe 362 includes a rear exhaust main pipe 368 connected to the reference device pipe 192 on the upstream side, and a plurality of rear exhaust branch pipes 370 connected to the rear exhaust main pipe 368. Each of the plurality of rear exhaust branch pipes 370 is provided with a valve 206. The plurality of rear exhaust branch pipes 370 are configured to join the exhaust pipe 200 connected to the downstream of the chambers 60, respectively.

Here, the wafer processing flow path A and the measurement flow path B in the other embodiment will be described. In the wafer processing system 300 configured as described above, the wafer processing flow path A refers to a flow path of a process gas when the process gas supplied from the gas source 140 flows in the front gas box group 306 or the rear gas box group 314, inside the upstream side pipe 144, the flow rate controller 142, and the downstream side pipe 146 of each gas box 80, the connection pipe 82, the chamber 60, and the exhaust pipe 200. The measurement flow path B refers to a flow path of a process gas when the process gas supplied from the gas source 140 flows inside the upstream side pipe 144, the flow rate controller 142, and the downstream side pipe 146 of each gas box 80 in the front gas box group 306, the front measurement pipe 330, the measuring instrument 170, the calibration system 190, the front exhaust pipe 360, and the exhaust pipe 200, or when the process gas supplied from the gas source 140 flows inside the upstream side pipe 144, the flow rate controller 142, and the downstream side pipe 146 of each gas box 80 in the rear gas box group 314, the rear measurement pipe 332, the measuring instrument 170, the calibration system 190, the rear exhaust pipe 362, and the exhaust pipe 200.

In the another embodiment above, when the process gas is supplied from one gas box 80 in the front gas box group 306 or the rear gas box group 314 to one chamber 60 in the wafer processing flow path A, a valve in one exhaust pipe 200 connected to the downstream of the chamber 60 is opened to exhaust the process gas through the one exhaust pipe 200. In this case, when the process gas is supplied from the one gas box 80 to the flow rate measuring device 120 in the measurement flow path B, a valve 206 in one front exhaust branch pipe 366 or rear exhaust branch pipe 370 connected to the one exhaust pipe 200, of the front exhaust pipe 360 or the rear exhaust pipe 362 connected to the downstream of the flow rate measuring device 120, is opened to exhaust the process gas through the one front exhaust branch pipe 366 or the rear exhaust branch pipe 370 and the one exhaust pipe 200. Therefore, the process gas supplied from one gas box 80, in any one of the wafer processing flow path A and the measurement flow path B, is exhausted from the one exhaust pipe 200 after merging.

In the present embodiment, the front exhaust main pipe 364 and the rear exhaust main pipe 368 are provided with a front exhaust main pipe valve 372 and a rear exhaust main pipe valve 374, respectively. When the process gas is supplied from one gas box 80 in the front gas box group 306 to the flow rate measuring device 120 in the measurement flow path B, the front exhaust main pipe valve 372 may be opened and the rear exhaust main pipe valve 374 may be closed. Conversely, when the process gas is supplied from one gas box 80 in the rear gas box group 314 to the flow rate measuring device 120 in the measurement flow path B, the rear exhaust main pipe valve 374 may be opened and the front exhaust main pipe valve 372 may be closed.

The wafer processing system 300 according to the other embodiment is configured as described above. Next, a method MT of measuring a gas flow rate using the flow rate measuring device 120 as a wafer processing method in the wafer processing system 300 will be described.

The method MT is executed using the flow rate measuring device 120 in order to obtain the gas flow rate in the wafer processing system 300. As the wafer processing system 300, the ones described above and shown in FIGS. 5 and 6 can be used. In the method MT, it is assumed that the flow rate of a process gas output from one flow rate controller 142 in one of the six gas boxes 80 in the front gas box group 306 of the wafer processing system 300 is measured. Hereinafter, when a gas box 80 is simply referred to, it refers to the above-mentioned one gas box. When a flow rate controller 142 is simply referred to, it refers to the above-mentioned one flow rate controller 142. However, the same method MT can be adopted when the process gas is supplied from a gas box 80 other than the one gas box 80 in the front gas box group 306 or when the process gas is supplied from one of the eight gas boxes 80 in the rear gas box group 314.

The method MT includes steps ST1 to ST16. In one embodiment, the method MT may further include step STA in addition to the steps ST1 to ST16. In one embodiment, the method MT may further include step STB. The step STA is a step of configuring the pressure sensors 184 and 186 and the temperature sensor 188 of the measuring instrument 170 in the flow control system by using a calibration system, and may use the step STA described in Patent Document 1. Further, the step STB is a step of verifying the reliability of capacity V₃ of the measuring instrument 170 by using the calibration system, and may use the step STB described in Patent Document 1.

In the step ST1 of the method MT, a first state is formed in which the following valves of the wafer processing system 300 are closed. In the present embodiment, the closed valves are the plurality of flow rate controller primary valves 150, the plurality of flow rate controller secondary valves 152, the first output valve 156, and the second output valve 162 of the plurality of gas boxes 80 in the front gas box group 306, and the front main pipe valve 350, the rear main pipe valve 352, the measuring instrument primary valve 180, the measuring instrument secondary valve 182, the reference device valve, the exhaust device valve 201, the front exhaust main pipe valve 372, the rear exhaust main pipe valve 374, the valve 204, and the valve 206 in the flow rate measuring device 120.

In the step ST2 of the method MT, from the first state, first, the flow rate controller secondary valve 152, the second output valve 162 of the gas box 80, the front main pipe valve 350, the measuring instrument primary valve 180, the measuring instrument secondary valve 182, the exhaust device valve 201, the front exhaust main pipe valve 372, and the valve 206 are opened. Subsequently, the downstream side pipe 146 in the gas box 80, the measurement pipe 172, the measuring instrument 170, and the reference device pipe 192 are evacuated by the exhaust device 130.

According to the steps ST1 and ST2, in the measurement pipe 172 of the present embodiment, the front main pipe valve 350 of the front measurement pipe 330 connected to the front gas box group 306 including the one gas box 80 used for measurement is opened, and the rear main pipe valve 352 of the rear measurement pipe 332 connected to the rear gas box group 314 not including the one gas box 80 is closed. Therefore, the measurement pipe 172 consists of three regions of the front measurement pipe 330 connected to the one gas box 80 used for measurement, the merging pipe 334, and the rear main pipe 346 on the downstream side of the rear main pipe valve 352 of the rear measurement pipe 332 connected to the rear gas box group 314. In other words, the measurement pipe 172 consists of a region excluding the rear measurement pipe 332 on the upstream side of the rear main pipe valve 352 in the rear measurement pipe 332 from a region where the front measurement pipe 330, the rear measurement pipe 332, and the merging pipe 334 are combined. In the steps ST1 to ST16, the measurement pipe 172 refers to a portion of the measurement pipe 172 including the above region.

The description of the steps ST3 to ST16 is omitted because they are the same as those of the steps ST3 to ST16 in the method MT of measuring the gas flow rate of the wafer processing method using the wafer processing system 300 according to the above one embodiment.

In the measurement pipe 172 in the other embodiment, in the steps ST1 to ST16, the front main pipe valve 350 of the front measurement pipe 330 connected to the front gas box group 306 including the one gas box 80 used for measurement is opened, and the rear main pipe valve 352 of the rear measurement pipe 332 connected to the rear gas box group 314 not including the one gas box 80 is closed. Therefore, the measurement pipe 172 consists of three regions of the front measurement pipe 330 connected to the one gas box 80 used for measurement, the merging pipe 334, and the rear main pipe 346 on the downstream side of the rear main pipe valve 352 of the rear measurement pipe 332 connected to the rear gas box group 314. In other words, the measurement pipe 172 consists of a region excluding the rear measurement pipe 332 on the upstream side of the rear main pipe valve 352 in the rear measurement pipe 332 from a region where the front measurement pipe 330, the rear measurement pipe 332, and the merging pipe 334 are combined.

Therefore, the volume of the region of the measurement pipe 172 is smaller than the volume of the measurement pipe 172 when the front main pipe valve 350 and the rear main pipe valve 352 are not provided. This makes it possible to improve the responsiveness of a change in the internal pressure of the flow rate measuring device 120 in a step, which requires the exhaust and filling of a process gas in the measurement pipe 172, among the steps ST1 to ST16. Specifically, it is possible to shorten the time required for evacuation in the step ST2, the time required for gas supply and pressure stabilization in the step ST3 for forming the second state in the step ST4, the time required for pressure increase and pressure stabilization in the third state in the step ST7, etc.

In the method MT, the flow rate Q may be obtained for all of the flow rate controllers 142 of the gas box 80. Further, the method MT may be sequentially executed for all of the plurality of gas boxes 80. Further, the method MT may be sequentially executed for all of the gas boxes in the rear gas box group 314.

The embodiments disclosed this time should be considered to be exemplary and not restrictive in all respects. The above embodiments may be omitted, replaced, or changed in various forms without departing from the appended claims and the gist thereof.

According to the present disclosure in some embodiments, it is possible to provide a technique capable of shortening the time required for gas flow rate measurement performed by using a flow rate measuring device in a substrate processing system.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing system comprising:
a chamber group including a plurality of chambers configured to process a substrate in a desired process gas;
a gas box group including a plurality of gas boxes configured to supply the process gas to each of the plurality of chambers;
a flow rate measuring device configured to measure a flow rate of the process gas supplied from the gas box group; and
an exhaust device connected to the chamber group and the flow rate measuring device,
wherein the flow rate measuring device includes a measuring instrument and a measurement pipe connected to the gas box group and the measuring instrument and configured to flow the process gas through the gas box group and the measuring instrument,
wherein the measurement pipe includes a plurality of branch pipes connected to each of the plurality of gas boxes, a main pipe connected to each of the plurality of branch pipes and the measuring instrument, and branch pipe valves provided in the plurality of branch pipes, and
wherein the measuring instrument includes one or more pressure sensors configured to measure an internal pressure of the measuring instrument, a temperature sensor configured to measure an internal temperature of the measuring instrument, a measuring instrument primary valve provided at an end portion of the side connected to the measurement pipe in the measuring instrument, and a measuring instrument secondary valve provided at an end portion of the side connected to the exhaust device.

2. The substrate processing system of claim 1, wherein the chamber group, the gas box group, and the measurement pipe are each provided in a plural number, and the plurality of measurement pipes include a main pipe valve provided in the main pipe.

3. The substrate processing system of claim 2, wherein the exhaust device includes an exhaust pipe connected to the chambers and provided with a valve, and a plurality of exhaust pipes connected to the flow rate measuring device and corresponding to the plurality of gas box groups,
wherein the plurality of exhaust pipes include an exhaust main pipe provided with a valve, and a plurality of exhaust branch pipes connected to the exhaust main pipe and provided with a valve, and
wherein the exhaust pipe connected to the chambers and the exhaust branch pipes merge.

4. The substrate processing system of claim 3, further comprising: a controller configured to control the gas box group so that when the process gas is output from one gas box in the gas box group, the process gas is not output from the other gas boxes.

5. The substrate processing system of claim 1, further comprising: a controller configured to control the gas box group so that when the process gas is output from one gas box in the gas box group, the process gas is not output from the other gas boxes.

6. A substrate processing system comprising:
a plurality of chamber groups including a plurality of chambers configured to process a substrate in a desired process gas;
a plurality of gas box groups including a plurality of gas boxes configured to supply the process gas to each of the plurality of chambers;
a flow rate measuring device configured to measure a flow rate of the process gas supplied from one of the plurality of gas box groups; and
an exhaust device connected to the chamber groups and the flow rate measuring device,
wherein the flow rate measuring device includes a measuring instrument and a plurality of measurement pipes connected to each of the plurality of gas box groups and the measuring instrument and configured to flow the process gas through the gas box groups and the measuring instrument,
wherein one of the measurement pipes includes a plurality of branch pipes connected to each of the plurality of gas boxes in the corresponding one gas box group, a main pipe connected to each of the plurality of branch pipes and the measuring instrument, and a main pipe valve provided in the main pipe, and
wherein the measuring instrument includes one or more pressure sensors configured to measure an internal pressure of the measuring instrument, a temperature sensor configured to measure an internal temperature of the measuring instrument, a measuring instrument primary valve provided at an end portion of the side connected to the measurement pipe in the measuring instrument, and a measuring instrument secondary valve provided at an end portion of the side connected to the exhaust device.

7. A method of processing a substrate in a substrate processing system, wherein the substrate processing system includes:
a chamber group including a plurality of chambers configured to process a substrate in a desired process gas;
a gas box group including a plurality of gas boxes configured to supply the process gas to each of the plurality of chambers;
a flow rate measuring device configured to measure a flow rate of the process gas supplied from the gas box group; and
an exhaust device connected to the chamber group and the flow rate measuring device,
wherein the flow rate measuring device includes a measuring instrument and a measurement pipe connected to the gas box group and the measuring instrument and configured to flow the process gas through the gas box group and the measuring instrument,
wherein the measurement pipe includes a plurality of branch pipes connected to each of the plurality of gas boxes, a main pipe connected to each of the plurality of branch pipes and the measuring instrument, and branch pipe valves provided in the plurality of branch pipes, and
wherein the measuring instrument includes one or more pressure sensors configured to measure an internal pressure of the measuring instrument, a temperature sensor configured to measure an internal temperature of the measuring instrument, a measuring instrument primary valve provided at an end portion of the side connected to the measurement pipe in the measuring instrument, and a measuring instrument secondary valve provided at an end portion of the side connected to the exhaust device,
the method comprising:
forming a closed state of the branch pipe valve in the branch pipe connected to another gas box other than one gas box that supplies the process gas whose flow rate is measured; and
in the closed state, measuring the flow rate of the process gas supplied from the one gas box that supplies the process gas whose flow rate is measured.

8. A method of processing a substrate in a substrate processing system, wherein the substrate processing system includes:
a plurality of chamber groups including a plurality of chambers configured to process a substrate in a desired process gas;
a plurality of gas box groups including a plurality of gas boxes configured to supply the process gas to each of the plurality of chambers;
a flow rate measuring device configured to measure a flow rate of the process gas supplied from one of the plurality of gas box groups; and
an exhaust device connected to the chamber groups and the flow rate measuring device,
wherein the flow rate measuring device includes a measuring instrument and a plurality of measurement pipes connected to each of the plurality of gas box groups and the measuring instrument and configured to flow the process gas through the gas box groups and the measuring instrument,
wherein one of the measurement pipes includes a plurality of branch pipes connected to each of the plurality of gas boxes in the corresponding one gas box group, a main pipe connected to each of the plurality of branch pipes and the measuring instrument, and a main pipe valve provided in the main pipe,
wherein the measuring instrument includes one or more pressure sensors configured to measure an internal pressure of the measuring instrument, a temperature sensor configured to measure an internal temperature of the measuring instrument, a measuring instrument primary valve provided at an end portion of the side connected to the measurement pipe in the measuring instrument, and a measuring instrument secondary valve provided at an end portion of the side connected to the exhaust device,
wherein the exhaust device includes an exhaust pipe connected to the chambers and provided with a valve, and a plurality of exhaust pipes connected to the flow rate measuring device and corresponding to the plurality of gas box groups,
wherein the plurality of exhaust pipes include an exhaust main pipe provided with a valve and a plurality of exhaust branch pipes connected to the exhaust main pipe and provided with a valve, and
wherein the exhaust pipe connected to the chambers and the exhaust branch pipes merge,
the method comprising:
forming a closed state of the main pipe valve of the measurement pipe connected to another gas box group other than one gas box group including one gas box that supplies the process gas whose flow rate is measured; and
in the closed state, measuring the flow rate of the process gas supplied from the one gas box that supplies the process gas whose flow rate is measured.
